(19) United States
(12) Patent Application Publication
(10) Pub. No.: US 2026/0165047 A1
(43) Pub. Date: Jun. 11, 2026

(54) METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yohei ARAKAKI, Ibo Hyogo (JP); Takeshi SHIBATA, Nonoichi Ishikawa (JP)

(21) Appl. No.: 19/180,061

(22) Filed: Apr. 15, 2025

Related U.S. Application Data
(63) Continuation of application No. PCT/JP2023/040976, filed on Nov. 14, 2023.

(30) Foreign Application Priority Data
Jul. 31, 2023 (JP) 2023-124516

(51) Int. Cl. H10P 30/20; H10D 30/01; H10D 30/63; H10D 62/832; H10D 62/834; H10P 30/28

(52) U.S. Cl. CPC H10P 30/2042; H10D 30/025; H10D 62/8325; H10D 62/834; H10P 30/28; H10D 30/63

(57) ABSTRACT

According to one embodiment, a method for manufacturing a semiconductor device includes forming a first metal layer containing a first metal element on a first face of a substrate of a structure. The substrate contains SiC. The method includes implanting a first element to the first face through the first metal layer. The first element contains at least one selected from the group consisting of He, Ne, Ar, Kr, Xe, Rn, Si, N, P, As, B, Al, and Ga. The method includes irradiating the first face with a laser through the first metal layer after the implanting.

### CROSS-REFERENCE TO RELATED APPLICATIONS

This is a continuation application of International Application PCT/JP2023/040976, filed on Nov. 14, 2023. This application also claims priority to Japanese Patent Application No. 2023-124516, filed on Jul. 31, 2023. The entire contents of which are incorporated herein by reference.

### FIELD

Embodiments described herein generally relate to a method for manufacturing a semiconductor device.

### BACKGROUND

It is desired to improve the characteristics of semiconductor devices.

### BRIEF DESCRIPTION OF THE DRAWINGS

FIG. 1 is a flowchart illustrating a method for manufacturing a semiconductor device according to a first embodiment;

FIG. 2 is a schematic cross-sectional view illustrating the method for manufacturing the semiconductor device according to the first embodiment;

FIG. 3 is a schematic cross-sectional view illustrating the method for manufacturing the semiconductor device according to the first embodiment;

FIG. 4 is a schematic cross-sectional view illustrating the method for manufacturing the semiconductor device according to the first embodiment;

FIG. 5 is a schematic cross-sectional view illustrating the method for manufacturing the semiconductor device according to the first embodiment;

FIG. 6 is a schematic cross-sectional view illustrating the method for manufacturing the semiconductor device according to the first embodiment;

FIG. 7 is a schematic cross-sectional view illustrating the method for manufacturing the semiconductor device according to the first embodiment;

FIG. 8 is a schematic cross-sectional view illustrating the method for manufacturing the semiconductor device according to the first embodiment;

FIG. 9 is a flowchart illustrating a method for manufacturing a semiconductor device according to a second embodiment;

FIG. 10 is a schematic cross-sectional view illustrating the method for manufacturing the semiconductor device according to the second embodiment;

FIG. 11 is a schematic cross-sectional view illustrating the method for manufacturing the semiconductor device according to the second embodiment;

FIG. 12 is a schematic cross-sectional view illustrating the method for manufacturing the semiconductor device according to the second embodiment;

FIG. 13 is a schematic cross-sectional view illustrating the method for manufacturing the semiconductor device according to the second embodiment;

FIG. 14 is a schematic cross-sectional view illustrating the method for manufacturing the semiconductor device according to the second embodiment; and

FIG. 15 is a schematic cross-sectional view illustrating a semiconductor device according to a third embodiment.

### DETAILED DESCRIPTION

According to one embodiment, a method for manufacturing a semiconductor device includes forming a first metal layer containing a first metal element on a first face of a substrate of a structure. The substrate contains SiC. The method includes implanting a first element to the first face through the first metal layer. The first element contains at least one selected from the group consisting of He, Ne, Ar, Kr, Xe, Rn, Si, N, P, As, B, Al, and Ga. The method includes irradiating the first face with a laser through the first metal layer after the implanting.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

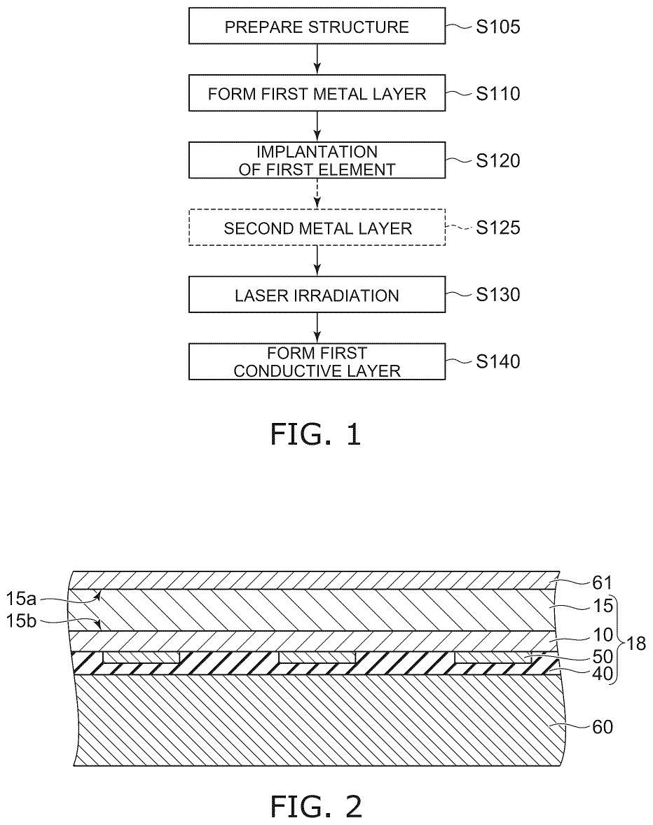

FIG. 1 is a flowchart illustrating a method for manufacturing a semiconductor device according to the first embodiment.

FIGS. 2 to 8 are schematic cross-sectional views illustrating the method for manufacturing the semiconductor device according to the first embodiment.

As shown in FIGS. 1 and 2, for example, a structure 18 is prepared (step S105). As shown in FIG. 2, the structure 18 includes a substrate 15. The substrate 15 may be, for example, a semiconductor substrate. The substrate 15 includes SiC. The substrate 15 includes a first face 15a. The substrate 15 may be, for example, at least a portion of a SiC wafer.

As shown in FIGS. 1 and 2, a first metal layer 61 is formed on the first face 15a of the structure 18 (step S110). The first metal layer 61 includes a first metal element.

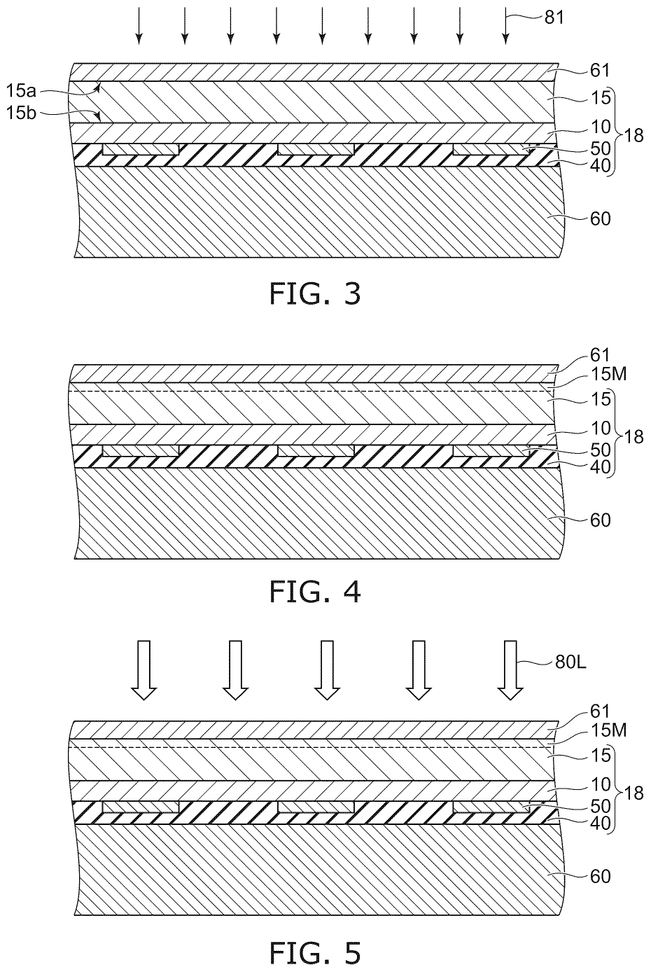

As shown in FIGS. 1 and 3, the first element 81 is implanted into the first face 15a through the first metal layer 61 (step S120). The first element 81 includes, for example, at least one selected from the group consisting of He, Ne, Ar, Kr, Xe, Rn, Si, N, P, As, B, Al, and Ga. The first element 81 may include, for example, at least one selected from the group consisting of He, Ne, Ar, Kr, Xe, Rn, and Si. The implantation is, for example, ion implantation. For example, ions of the first element 81 are implanted.

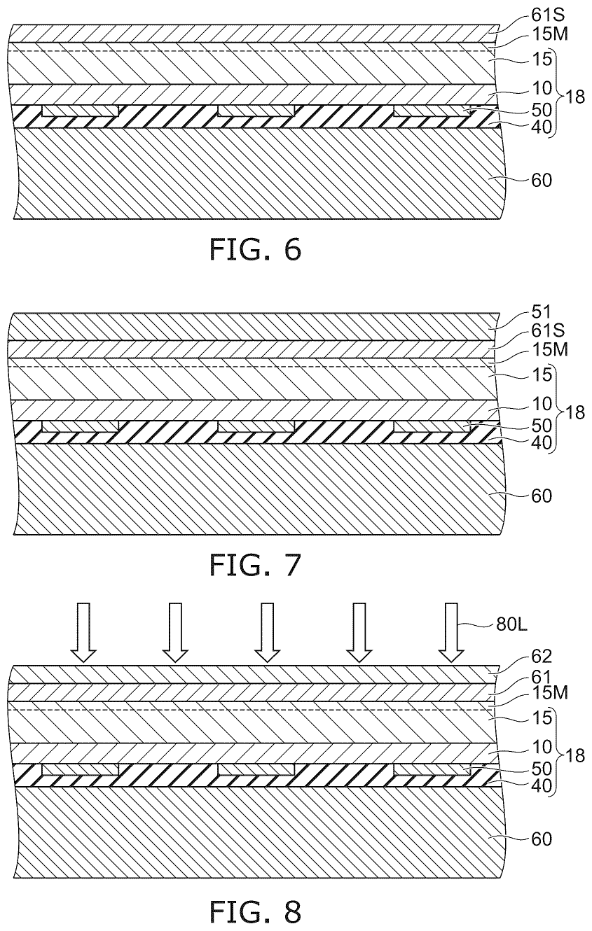

As shown in FIGS. 1 and 5, after the implantation, the first face 15a is irradiated with a laser 80L through the first metal layer 61 (step S130). For example, laser annealing is performed. As a result, as shown in FIG. 6, a silicide layer 61S is formed from at least a portion of the first metal layer 61.

In the embodiment, after the first metal layer 61 is formed, the first element 81 is implanted through the first metal layer 61. Thereby, a low resistance ohmic contact can be stably obtained. This is considered to be because a portion of the first metal element contained in the first metal layer 61 is introduced into the substrate 15 by implanting the first element 81. For example, a knock-on phenomenon may occur.

For example, the first metal element is introduced relatively uniformly and stably near the first face 15a of the substrate 15. As a result, a mixed layer (a mixed region 15M to be described later) having a high reaction rate of silicide reaction is uniformly formed. Subsequent annealing using laser irradiation effectively turns the highly reactive mixed layer into silicide. Thereby, the silicide layer 61S being uniform is stably formed. This results in low electrical resistance. High flatness can be obtained. For example, high flatness and low electrical resistance can be obtained. According to the embodiment, a method for manufacturing a semiconductor device that can improve characteristics is provided. For example, the silicide layer 61S being highly flat can be obtained. Surface morphology can be improved.

In the embodiment, laser annealing is performed after the implantation of the first element 81 through the first metal layer 61. Thereby, the silicide layer 61S being stable can be obtained even by low power laser irradiation. For example, the laser 80L having a low energy density can be applied. This allows the laser irradiation process to be made more efficient. For example, high throughput can be obtained. For example, energy consumption can be reduced.

As shown in FIG. 2, a substrate 15 may include a second face 15b. The structure 18 may include a semiconductor layer 10 in addition to the substrate 15. The structure 18 may include a conductive layer 50 and an insulating member 40.

For example, the semiconductor layer 10 is provided between the substrate 15 and the insulating member 40. The conductive layer 50 is provided between the semiconductor layer 10 and the insulating member 40. The conductive layer 50 may be, for example, an electrode layer. The insulating member 40 is, for example, a passivation layer. The second face 15b is located between the semiconductor layer 10 and the first face 15a. The first face 15a corresponds to, for example, a surface on which an ohmic electrode is provided. For example, the semiconductor layer 10 includes SiC.

For example, at least a portion of the semiconductor layer 10 may be epitaxially grown on a base (SiC wafer) that becomes the substrate 15. The conductive layer 50 and the insulating member 40 are formed on the semiconductor layer 10. After this, the substrate may be thinned. For example, processing such as grinding may be performed. In this way, the preparation of the structure 18 (step S105) may include reducing the thickness of the base serving as the substrate 15.

As shown in FIGS. 2 and 3, the structure 18 may be fixed to the support member 60 during implantation of the first element 81. Mechanical strength increases and stable processing can be performed.

As shown in FIGS. 3 and 4, the mixed region 15M is formed by implanting the first element 81. The mixed region 15M includes, for example, Si, C, and the first metal element. For example, the implantation of the first element 81 may include moving a portion of the first metal element to a region including the first face 15a of the substrate 15. For example, by implanting the first element 81, the mixed region 15M is formed in the region including the first face 15a of the substrate 15. The formation of the mixed region 15M is caused by the knock-on phenomenon, as described above.

The first metal element includes, for example, at least one selected from the group consisting of Ti, Co, Ni, Mo, Ta, W, and Pt. The mixed region 15M containing such a first metal element, Si, and carbon is formed. For example, the first metal element is uniformly introduced near the first face 15a. The mixed region 15M may further include the first element 81. Ti, Co, Ni, Mo, Ta, W, and Pt can react with Si to form the silicide.

As shown in FIG. 5, the first metal layer 61 and the mixed region 15M are irradiated with the laser 80L. Thereby, as shown in FIG. 6, the silicide layer 61S is formed. Thus, the irradiation includes forming the silicide layer 61S from the first metal layer 61. After the silicide layer 61S is formed, the mixed region 15M may remain. At least a portion of the mixed region 15M may be amorphous. At least a portion of the mixed region 15M may include crystals (including polycrystals).

In the embodiment, the thickness of the first metal layer 61 is preferably not less than 10 nm and not more than 100 nm. If the first metal layer 61 is too thin, it becomes difficult to obtain a uniform silicide layer 61S, for example. If the thickness of the first metal layer 61 is too thick, energy becomes excessively large during, for example, implantation of the first element 81 and/or laser irradiation.

In the embodiment, the first element 81 may include at least one selected from the group consisting of Ar, B, P, and As. Thereby, it becomes easier to form the mixed region 15M with an appropriate thickness. Good compatibility with other processes. For example, an ion implanter used for imparting conductivity may be used.

The implantation of the first element 81 may include implantation of the first metal element.

In the embodiment, the first element 81 may include Si. For example, a Si-rich mixed region 15M is obtained. For example, silicon can be easily introduced into the first metal layer 61. Thereby, a uniform silicide layer 61S can be efficiently formed. For example, a portion of silicon is introduced into the first metal layer 61. As a result, a region is formed in which the substrate 15, the region formed by knock-on, and the region in which silicon is implanted into the first metal layer 61 are continuous.

As shown in FIGS. 1 and 7, a first conductive layer 51 may be formed on the silicide layer 61S after irradiation with the laser 80L (step S140). The first conductive layer 51 functions, for example, as an electrode. The first conductive layer 51 may include metal such as aluminum, copper, or gold, for example. The first conductive layer 51 makes ohmic contact with the substrate 15 through the silicide layer 61S with low resistance.

As shown in FIG. 1, a second metal layer 62 (see FIG. 8) may be formed (step S125) between the implantation (step S120) and the irradiation (step S130). As shown in FIG. 8, the second metal layer 62 is formed on the first metal layer 61. The second metal layer 62 includes a second metal element. The second metal element may include, for example, at least one selected from the group consisting of Ti, Co, Ni, Mo, Ta, W, and Pt. The second metal element may be the same as or different from the first metal element.

For example, the first metal layer 61 being thin is formed and the first element 81 is implanted. Thereby, the desired mixed region 15M is efficiently formed. Then, the second metal layer 62 is formed. The silicide layer 61S can be efficiently formed from the first metal layer 61 and the second metal layer 62 by laser irradiation. The silicide layer 61S having a desired thickness can be stably formed.

The second metal element may be the same as the first metal element. The second metal element may be different from the first metal element.

As already explained, the structure 18 may further include the semiconductor layer 10 containing SiC. By providing the semiconductor layer 10, higher quality can be obtained. The semiconductor layer 10 is an epitaxially grown layer. In the embodiment, the laser irradiation is performed to form the silicide layer 61S. Thereby, the target region (the region including the first metal layer 61 and the mixed region 15M) can be locally and effectively heated. Damage to the surface device structure (semiconductor layer 10 and conductive layer 50) is suppressed. The temperature of the surface device structure (semiconductor layer 10 and conductive layer 50) that increases due to laser irradiation is, for example, not less than 50° C. and not more than 1000° C. The temperature may be, for example, 100° C. or lower.

In the embodiment, the power of the laser 80L is, for example, not less than 1.0 J/cm² and not more than 3.0 J/cm². Good ohmic contact can be obtained while suppressing damage to the surface device structure (semiconductor layer 10 and conductive layer 50).

### Second Embodiment

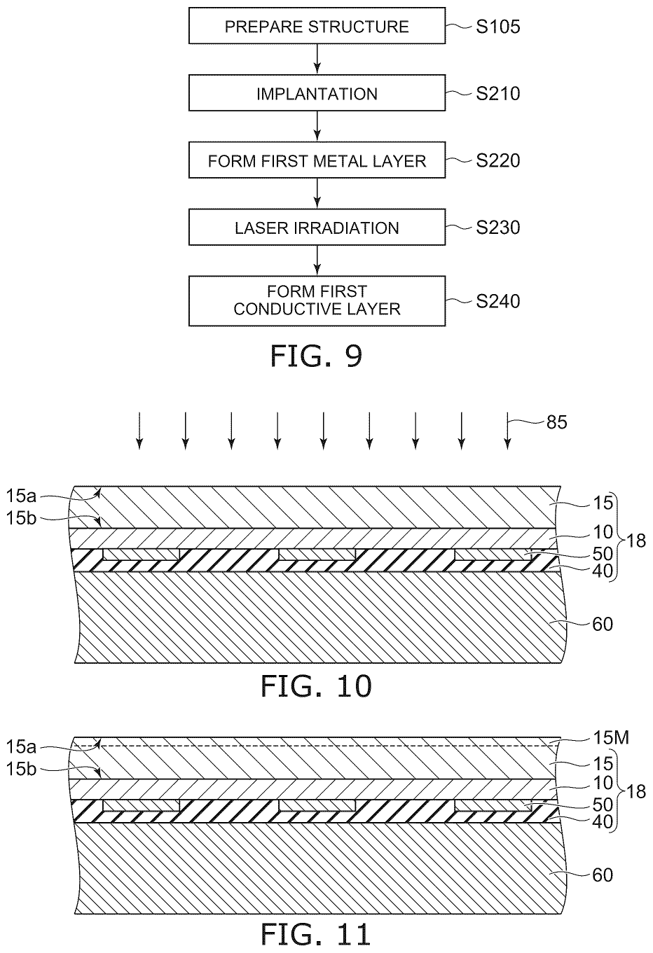

FIG. 9 is a flowchart illustrating a method for manufacturing a semiconductor device according to the second embodiment.

FIGS. 10 to 14 are schematic cross-sectional views illustrating the method for manufacturing the semiconductor device according to the second embodiment.

As shown in FIG. 9, in the second embodiment, the first metal layer 61 is formed (step S220) after the implantation (step S210). After that, the irradiation with the laser 80L (step S230) is performed. Except for the order of such steps, the configuration described in connection with the first embodiment may be applied to the second embodiment.

For example, as shown in FIG. 10, the structure 18 is prepared (step S105). As shown in FIG. 10, the structure 18 includes the substrate 15. The substrate 15 includes SiC. The substrate 15 includes the first face 15a.

As shown in FIG. 10, a metal element 85 for implantation is implanted into the first face 15a of the structure 18 (step S210). The metal element 85 for implantation includes, for example, at least one selected from the group consisting of Ti, Co, Ni, Mo, Ta, W, and Pt.

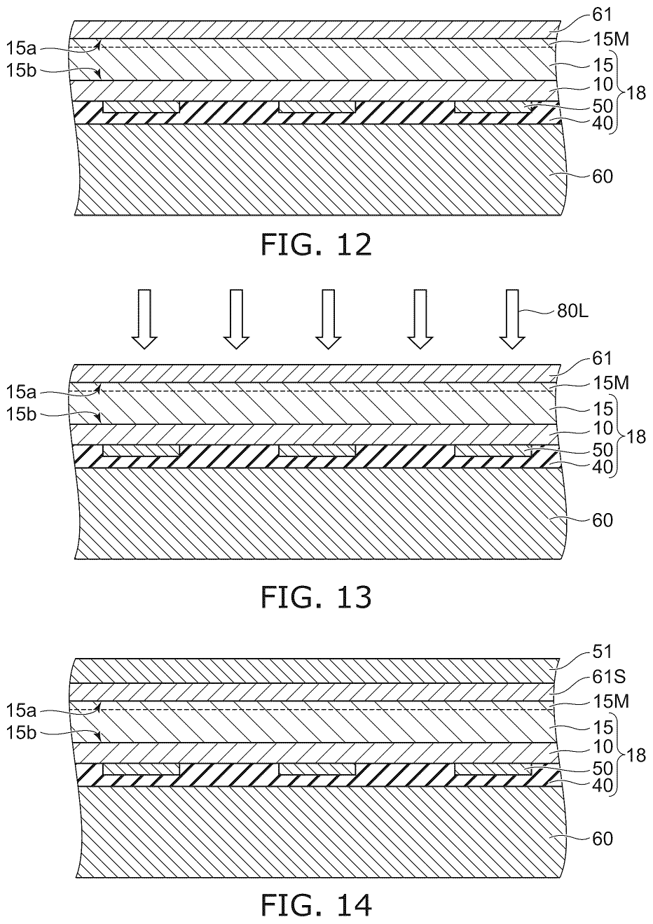

As shown in FIG. 11, by implanting the metal element 85, the mixed region 15M is formed near the first face 15a. The mixed region 15M is a region including the first face 15a. The mixed region 15M includes Si, C, and the metal element 85 for implantation.

As shown in FIG. 12, after the implantation, the first metal layer 61 containing the first metal element is formed on the first face 15a (step S220). As shown in FIG. 13, the first face 15a is irradiated with the laser 80L through the first metal layer 61 (step S230).

In the second embodiment, the mixed region 15M is formed by implanting the metal element 85 before forming the first metal layer 61. By implanting the metal element 85 with low energy, the mixed region 15M can be efficiently formed. By irradiating the mixed region 15M containing the metal element 85 and the first metal layer 61 containing the first metal element with the laser 80L, the silicide layer 61S can be efficiently formed. At least a portion of the silicide layer 61S may be formed from at least a portion of the first metal layer 61. A portion of the silicide layer 61S may be formed from at least a portion of the mixed region 15M. In this way, the irradiation with the laser 80L (step S230) may include forming at least a portion of the silicide layer 61S from the first metal layer 61.

For example, a first reference example can be considered in which the first metal layer 61 is formed after implanting Ar ions or the like, and then laser irradiation is performed. In the first reference example, an amorphous region is formed by implanting Ar ions or the like. Thereby, it is possible to form silicide using the laser 80L with low power. However, in the first reference example, the mixed region 15M is not formed. In the first reference example, the metal element is supplied only from the first metal layer 61 formed on the surface in the silicide reaction. The reaction region is only in the vicinity of the first metal layer 61. For this reason, for example, there is a limit to reduce the electrical resistance.

In contrast, in the embodiment, the mixed region 15M is formed by implanting the metal element 85. After that, the first metal layer 61 is formed, and the laser 80L is further irradiated. The laser 80L irradiates the mixed region 15M and the first metal layer 61 to form the silicide layer 61S. The mixed region 15M functions as a transition region, for example. Stress and the like are relaxed when forming the silicide layer 61S. For example, the silicide layer 61S can be efficiently formed while maintaining good film quality. For example, good morphology can be obtained. For example, a surface with good flatness is obtained.

As shown in FIGS. 9 and 14, the first conductive layer 51 may be formed on the silicide layer 61S after the laser 80L irradiation (step S230).

Also in the second embodiment, the first metal element includes at least one selected from the group consisting of Ti, Co, Ni, Mo, Ta, W, and Pt. In the second embodiment, the thickness of the first metal layer 61 may be not less than 10 nm and not more than 500 nm. Also in the second embodiment, the structure 18 may further include the semiconductor layer 10 containing SiC. In the second embodiment, the structure 18 may include the conductive layer 50 and the insulating member 40.

In the first embodiment and the second embodiment, the structure 18 may be separated from the support member 60 after the laser irradiation or after the formation of the first conductive layer 51. A semiconductor device is thereby obtained.

### Third Embodiment

The third embodiment relates to a semiconductor device.

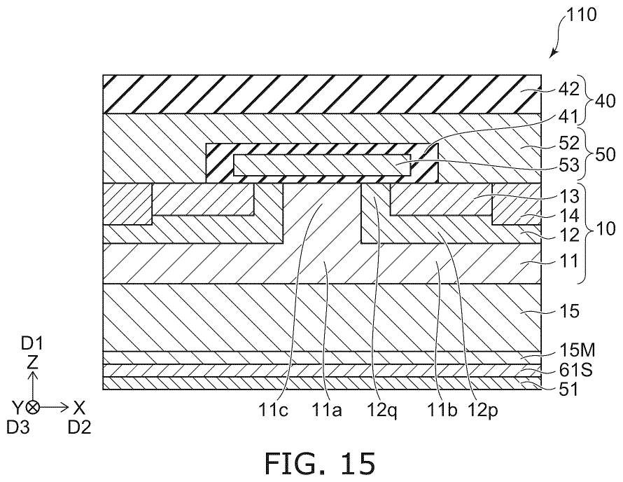

FIG. 15 is a schematic cross-sectional view illustrating a semiconductor device according to the third embodiment.

As shown in FIG. 15, a semiconductor device 110 according to the embodiment includes the first conductive layer 51, the semiconductor layer 10, the substrate 15, the silicide layer 61S, and the mixed region 15M. The semiconductor layer 10 includes SiC. The substrate 15 includes SiC. The substrate 15 is provided between first conductive layer 51 and semiconductor layer 10. The silicide layer 61S is provided between the first conductive layer 51 and the substrate 15. The silicide layer 61S contains the first metal element and silicon. The mixed region 15M is provided between silicide layer 61S and substrate 15. The mixed region 15M includes the first metal element, silicon, and carbon.

The first metal element includes at least one selected from the group consisting of Ti, Co, Ni, Mo, Ta, W, and Pt. Good ohmic contact can be obtained between the first conductive layer 51 and the substrate 15. Low electrical resistance can be obtained. For example, low on-resistance can be obtained.

As shown in FIG. 15, in this example, the semiconductor device 110 includes a second conductive layer 52 and a third conductive layer 53. The semiconductor layer 10 includes a first semiconductor region 11, a second semiconductor region 12, a third semiconductor region 13, and a fourth semiconductor region 14. A first direction D1 from the first conductive layer 51 to the second conductive layer 52 is defined as a Z-axis direction. One direction perpendicular to the Z-axis direction is defined as an X-axis direction. A direction perpendicular to the Z-axis direction and the X-axis direction is defined as a Y-axis direction.

The first semiconductor region 11 is of a first conductivity type (for example, n-type). The first semiconductor region 11 includes a first partial region 11a, a second partial region 11b, and a third partial region 11c. A second direction D2 from the first partial region 11a to the second partial region 11b crosses the first direction D1. The second direction D2 may be the X-axis direction. The third partial region 11c is provided between the first partial region 11a and the third conductive layer 53 in the first direction D1.

The second semiconductor region 12 is of a second conductivity type (for example, p-type). The third semiconductor region 13 is of the first conductivity type. The fourth semiconductor region 14 is of the second conductivity type. The impurity concentration of the first conductivity type in the third semiconductor region 13 is higher than the impurity concentration of the first conductivity type in the first semiconductor region 11. The impurity concentration of the second conductivity type in the fourth semiconductor region 14 is higher than the impurity concentration of the second conductivity type in the second semiconductor region 12.

A portion 12p of the second semiconductor region 12 is located between the second partial region 11b and the third semiconductor region 13 in the first direction D1. Another portion 12q of the second semiconductor region 12 is located between the third partial region 11c and the fourth semiconductor region 14 in the second direction D2. The third semiconductor region 13 is located between the other portion 12q of the second semiconductor region 12 and the fourth semiconductor region 14 in the second direction D2.

The second conductive layer 52 is electrically connected to the third semiconductor region 13 and the fourth semiconductor region 14. The insulating member 40 may include a first insulating region 41 and a second insulating region 42. At least a portion of the first insulating region 41 is provided between the third partial region 11c and the third conductive layer 53. The second conductive layer 52 is provided between the semiconductor layer 10 and the second insulating region 42. The third conductive layer 53 may extend along a third direction D3 crossing a plane including the first direction D1 and the second direction D2. The third direction D3 may be, for example, the Y-axis direction.

A current flowing between the first conductive layer 51 and the second conductive layer 52 can be controlled by a potential of the third conductive layer 53. The semiconductor device 110 is, for example, a transistor. The first conductive layer 51 may be, for example, a drain electrode. The second conductive layer 52 may be a source electrode. The third conductive layer 53 may be a gate electrode.

The semiconductor device 110 according to the embodiment may be, for example, a diode. The first conductive layer 51 may be any electrode layer. Good ohmic contact can be obtained in the semiconductor device 110 according to the embodiment. A semiconductor device with improved characteristics can be provided. For example, low electrical resistance can be obtained. For example, high flatness can be obtained. For example, high flatness and low electrical resistance can be obtained.

In the embodiment, for example, the substrate 15 may include at least one selected from the group consisting of 4H-SiC, 6H-SiC, and 3C-SiC.

For example, the first conductivity type impurity includes at least one selected from the group consisting of N, P, and As. For example, the second conductivity type impurity includes at least one selected from the group consisting of B, Al, and Ga.

In the embodiments, information regarding length and thickness is obtained by electron microscopy or the like. Information regarding the composition of the material can be obtained by SIMS (Secondary Ion Mass Spectrometry), EDX (Energy dispersive X-ray spectroscopy), or the like.

The embodiments may include the following Technical proposals:

### (Technical Proposal 1)

A method for manufacturing a semiconductor device, the method comprising:
forming a first metal layer containing a first metal element on a first face of a substrate of a structure, the substrate containing SiC;
implanting a first element to the first face through the first metal layer, the first element containing at least one selected from the group consisting of He, Ne, Ar, Kr, Xe, Rn, Si, N, P, As, B, Al, and Ga; and
irradiating the first face with a laser through the first metal layer after the implanting.

### (Technical Proposal 2)

The method for manufacturing the semiconductor device according to Technical proposal 1, wherein
the implanting includes moving a portion of the first metal element to a region including the first face of the substrate.

### (Technical Proposal 3)

The method for manufacturing the semiconductor device according to Technical proposal 1, wherein
a mixed region is formed in a region including the first face of the substrate by the implanting, and
the mixed region includes Si, C, and the first metal element.

### (Technical Proposal 4)

The method for manufacturing the semiconductor device according to Technical proposal 2 or 3, wherein

the first metal element includes at least one selected from the group consisting of Ti, Co, Ni, Mo, W, Ta, and Pt.

### (Technical Proposal 5)

The method for manufacturing the semiconductor device according to any one of Technical proposals 2-4, wherein
the first element includes at least one selected from the group consisting of Ar, B, P, and As.

### (Technical Proposal 6)

The method for manufacturing the semiconductor device according to any one of Technical proposals 2-4, wherein

The first element includes Si.

### (Technical Proposal 7)

The method for manufacturing the semiconductor device according to any one of Technical proposals 2-6, wherein
the irradiating includes forming a silicide layer from the first metal layer.

### (Technical Proposal 8)

The method for manufacturing the semiconductor device according to Technical proposal 7, further comprising:
forming a first conductive layer on the silicide layer after the irradiating.

### (Technical Proposal 9)

The method for manufacturing the semiconductor device according to any one of Technical proposals 1-8, wherein
a thickness of the first metal layer is not less than 10 nm and not more than 100 nm.

### (Technical Proposal 10)

The method for manufacturing the semiconductor device according to any one of Technical proposals 1-9, further comprising:
forming a second metal layer containing a second metal element on the first metal layer between the implanting and the irradiating.

### (Technical Proposal 11)

The method for manufacturing the semiconductor device according to Technical proposal 10, wherein
the second metal element is the same as the first metal element.

### (Technical Proposal 12)

The method for manufacturing the semiconductor device according to any one of Technical proposals 1-11, wherein
the structure further includes a semiconductor layer containing SiC,
the substrate further includes a second face, and
the second face is located between the first face and the semiconductor layer.

### (Technical Proposal 13)

The method for manufacturing the semiconductor device according to Technical proposal 12, wherein
a temperature of the semiconductor layer that increases due to the irradiating is 100° C. or less.

### (Technical Proposal 14)

A method for manufacturing a semiconductor device, the method comprising:
implanting a metal element for implantation into a first face of a substrate of a structure, the substrate containing SiC;
forming a first metal layer containing a first metal element on the first face after the implanting; and
irradiating the first face with a laser through the first metal layer.

### (Technical Proposal 15)

The method for manufacturing the semiconductor device according to Technical proposal 14, wherein
the implanting includes forming a mixed region in a portion of the substrate,
the mixed region includes the first face, and
the mixed region includes Si, C, and the metal element for implantation.

### (Technical Proposal 16)

The method for manufacturing the semiconductor device according to Technical proposal 14 or 15, wherein
the metal element for implantation includes at least one selected from the group consisting of Ti, Co, Ni, Mo, Ta, W, and Pt.

### (Technical Proposal 17)

The method for manufacturing the semiconductor device according to any one of Technical proposals 14-16, wherein
the first metal element includes at least one selected from the group consisting of Ti, Co, Ni, Mo, Ta, W, and Pt.

### (Technical Proposal 18)

The method for manufacturing the semiconductor device according to any one of Technical proposals 14-17, wherein

The irradiating includes forming a silicide layer from the first metal layer.

### (Technical Proposal 19)

The method for manufacturing the semiconductor device according to any one of Technical proposals 1-18, further comprising:
preparing the structure,
the preparing the structure including reducing a thickness of a base serving as the substrate.

### (Technical Proposal 20)

A semiconductor device, comprising:
a first conductive layer;
a semiconductor layer containing SiC;
a substrate containing SiC, the substrate being provided between the first conductive layer and the semiconductor layer;
a silicide layer provided between the first conductive layer and the substrate, the silicide layer containing a first metal element and silicon; and
a mixed region provided between the silicide layer and the substrate, the mixed region containing the first metal element, silicon, and carbon.

According to the embodiment, a method for manufacturing a semiconductor device that can improve characteristics and a semiconductor device can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices or the structure such as substrates, semiconductor layers, silicide layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all methods for manufacturing semiconductor devices practicable by an appropriate design modification by one skilled in the art based on the methods for manufacturing semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, the method comprising:
forming a first metal layer containing a first metal element on a first face of a substrate of a structure, the substrate containing SiC;
implanting a first element to the first face through the first metal layer, the first element containing at least one selected from the group consisting of He, Ne, Ar, Kr, Xe, Rn, Si, N, P, As, B, Al, and Ga; and
irradiating the first face with a laser through the first metal layer after the implanting.

2. The method according to claim 1, wherein
the implanting includes moving a portion of the first metal element to a region including the first face of the substrate.

3. The method according to claim 1, wherein
a mixed region is formed in a region including the first face of the substrate by the implanting, and
the mixed region includes Si, C, and the first metal element.

4. The method according to claim 2, wherein
the first metal element includes at least one selected from the group consisting of Ti, Co, Ni, Mo, W, Ta, and Pt.

5. The method according to claim 2, wherein
the first element includes at least one selected from the group consisting of Ar, B, P, and As.

6. The method according to claim 2, wherein
The first element includes Si.

7. The method according to claim 1, further comprising:
forming a second metal layer containing a second metal element on the first metal layer between the implanting and the irradiating.

8. A method for manufacturing a semiconductor device, the method comprising:
implanting a metal element for implantation into a first face of a substrate of a structure, the substrate containing SiC;
forming a first metal layer containing a first metal element on the first face after the implanting; and
irradiating the first face with a laser through the first metal layer.

9. The method according to claim 8, wherein
the implanting includes forming a mixed region in a portion of the substrate,
the mixed region includes the first face, and
the mixed region includes Si, C, and the metal element for implantation.

10. The method according to claim 8, wherein
the metal element for implantation includes at least one selected from the group consisting of Ti, Co, Ni, Mo, Ta, W, and Pt.

11. The method according to claim 8, wherein
the first metal element includes at least one selected from the group consisting of Ti, Co, Ni, Mo, Ta, W, and Pt.

12. The method according to claim 9, wherein
the first metal element includes at least one selected from the group consisting of Ti, Co, Ni, Mo, Ta, W, and Pt.

13. The method according to claim 10, wherein
the first metal element includes at least one selected from the group consisting of Ti, Co, Ni, Mo, Ta, W, and Pt.
